(19) United States
(12) Patent Application Publication
(10) Pub. No.: US 2024/0057398 A1
(43) Pub. Date: Feb. 15, 2024

(54) DISPLAY DEVICE

(71) Applicant: Samsung Display Co., LTD., Yongin-si (KR)

(72) Inventors: Jun Hyun PARK, Yongin-si (KR); Hyeong Seok KIM, Yongin-si (KR); HEEJEAN PARK, Yongin-si (KR); Min Jae JEONG, Yongin-si (KR)

(21) Appl. No.: 18/344,536

(22) Filed: Jun. 29, 2023

(30) Foreign Application Priority Data
Aug. 10, 2022 (KR) 10-2022-0100193

(51) Int. Cl. H10K 59/123; H10K 59/121; H10K 59/131

(52) U.S. Cl. CPC H10K 59/123; H10K 59/1213; H10K 59/1216; H10K 59/1315

(57) ABSTRACT

The present disclosure relates to a display device, and one or more embodiments provides a display device including a substrate, a transistor above the substrate, a pixel electrode connected to the transistor, an extension electrode connected between the transistor and the pixel electrode, an additional capacitor electrode at a same layer as the extension electrode, overlapping the pixel electrode, and to which a constant voltage is applied, a light-emitting layer above the pixel electrode, and a common electrode above the light-emitting layer.

### CROSS-REFERENCE TO RELATED APPLICATION

This application claims priority to, and the benefit of, Korean Patent Application No. 10-2022-0100193 filed in the Korean Intellectual Property Office on Aug. 10, 2022, the entire contents of which are incorporated herein by reference.

### BACKGROUND

### 1. Field

The present disclosure relates to a display device.

### 2. Description of the Related Art

A display device is a device for displaying an image, and includes a liquid crystal display (LCD), an organic light-emitting diode (OLED) display, and the like. The display device is used in various electronic devices, such as a mobile phone, a navigation device, a digital camera, an electronic book, a portable game machine, and various terminals.

An organic light-emitting display device includes two electrodes and an organic light-emitting layer interposed therebetween, wherein electrons injected from one electrode, and holes injected from another electrode, are combined in the organic light-emitting layer to generate excitons. The generated excitons are changed to a ground state from an excited state, releasing energy to emit light.

Such an organic light-emitting display device includes a plurality of pixels including an organic light-emitting diode, which is a self-emissive element. In each pixel, a plurality of transistors for driving the organic light-emitting diode and at least one capacitor are formed. The plurality of transistors may include a switching transistor and a driving transistor.

The above information disclosed in this Background section is only for enhancement of understanding of the background of the described technology, and therefore it may contain information that does not form the prior art that is already known in this country to a person of ordinary skill in the art.

### SUMMARY

Embodiments provide a display device that may perform stable driving by allowing each pixel to include an additional capacitor.

One or more embodiments provide a display device including a substrate, a transistor above the substrate, a pixel electrode connected to the transistor, an extension electrode connected between the transistor and the pixel electrode, an additional capacitor electrode at a same layer as the extension electrode, overlapping the pixel electrode, and to which a constant voltage is applied, a light-emitting layer above the pixel electrode, and a common electrode above the light-emitting layer.

The extension electrode and the additional capacitor electrode may include a transparent conductive oxide.

The additional capacitor electrode may be connected to a driving voltage line to which a driving voltage is applied.

The transistor may include a first gate electrode above the substrate, a semiconductor that overlaps the first gate electrode, and that includes a first area, a channel, and a second area, a second gate electrode overlapping the channel, a source electrode connected to the first area, and a drain electrode connected to the second area, and connected to the pixel electrode.

The drain electrode may be connected to the second gate electrode.

The driving voltage line may be at a same layer as the source electrode and the drain electrode.

The display device may further include a first storage electrode at a same layer as the semiconductor, and a second storage electrode at a same layer as the first gate electrode, and overlapping the first storage electrode.

The first storage electrode may overlap the driving voltage line.

The semiconductor may include an oxide semiconductor material.

The substrate may include a display area, and a peripheral area adjacent to the display area, wherein the display area includes a first display area, a second display area outside the first display area, and a third display area inside the first display area.

In the first display area, the transistor may be connected to the pixel electrode through the extension electrode, wherein, in the second display area and in the third display area, respective transistors are connected to respective pixel electrodes through respective extension electrodes.

The display device may further include a driving circuit part in the second display area, wherein at least some of the pixel electrodes in the second display area overlap the driving circuit part.

The display device may further include an electronic module in the third display area, wherein at least some of the pixel electrodes in the third display area overlap the electronic module.

The pixel electrode may include a pixel electrode of a red pixel, a pixel electrode of a green pixel, and a pixel electrode of a blue pixel.

The additional capacitor electrode may overlap all of the pixel electrode of the red pixel, all of the pixel electrode of the green pixel, and all of the pixel electrode of the blue pixel.

The additional capacitor electrode might not overlap at least some of the pixel electrode of the red pixel, the pixel electrode of the green pixel, or the pixel electrode of the blue pixel.

An overlapping ratio of the additional capacitor electrode and the pixel electrode of the red pixel, an overlapping ratio of the additional capacitor electrode and the pixel electrode of the green pixel, and an overlapping ratio of the additional capacitor electrode and the pixel electrode of the blue pixel may be different.

The display device may further include a data line to which a data voltage is applied, wherein the pixel electrode of the blue pixel defines an opening that overlaps the data line, and wherein the additional capacitor electrode defines an opening that overlaps the data line.

Each of pixels may include the extension electrode, wherein an extension electrode of a first pixel and an extension electrode of a second pixel are at different respective layers.

Each of the pixels may include the additional capacitor electrode, wherein an additional capacitor electrode of the first pixel and an additional capacitor electrode of the second pixel are at different respective layers.

According to the embodiments, each pixel of a display device may include an additional capacitor to ensure stable driving.

### BRIEF DESCRIPTION OF THE DRAWINGS

FIG. 1 illustrates a schematic top plan view of a display device according to one or more embodiments.

FIG. 2 illustrates a cross-sectional view taken along the line Il-Il of FIG. 1.

FIG. 3 illustrates a circuit diagram of one pixel of a display device according to one or more embodiments.

FIG. 4 illustrates a schematic view of a pixel positioned in a first display area of a display device according to one or more embodiments.

FIG. 5 illustrates a cross-sectional view of a pixel positioned in a first display area of a display device according to one or more embodiments.

FIG. 6 illustrates a schematic view of a pixel positioned in a second display area of a display device according to one or more embodiments.

FIG. 7 illustrates a cross-sectional view of a pixel positioned in a second display area of a display device according to one or more embodiments.

FIG. 8 illustrates a schematic view of a pixel positioned in a third display area of a display device according to one or more embodiments.

FIG. 9 illustrates a cross-sectional view of a pixel positioned in a third display area of a display device according to one or more embodiments.

FIG. 10 to FIG. 15 illustrate top plan views of some constituent elements of a display device according to one or more embodiments.

FIG. 16 and FIG. 17 illustrate cross-sectional views of a display device according to one or more embodiments.

FIG. 18 illustrates a cross-sectional view of a display device according to one or more embodiments.

FIG. 19 illustrates a circuit diagram of one pixel of a display device according to one or more embodiments.

### DETAILED DESCRIPTION

Aspects of some embodiments of the present disclosure and methods of accomplishing the same may be understood more readily by reference to the detailed description of embodiments and the accompanying drawings. Hereinafter, embodiments will be described in more detail with reference to the accompanying drawings. The described embodiments, however, may have various modifications and may be embodied in different forms, and should not be construed as being limited to only the illustrated embodiments herein. Rather, these embodiments are provided as examples so that this disclosure will be thorough and complete, and will fully convey the aspects of the present disclosure to those skilled in the art, and it should be understood that the present disclosure covers all the modifications, equivalents, and replacements within the idea and technical scope of the present disclosure.

Accordingly, processes, elements, and techniques that are not necessary to those having ordinary skill in the art for a complete understanding of the aspects of the present disclosure may not be described.

Unless otherwise noted, like reference numerals, characters, or combinations thereof denote like elements throughout the attached drawings and the written description, and thus, descriptions thereof will not be repeated. Further, parts that are not related to, or that are irrelevant to, the description of the embodiments might not be shown to make the description clear.

In the drawings, the relative sizes of elements, layers, and regions may be exaggerated for clarity. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result, for example, of manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Thus, the regions illustrated in the drawings are schematic in nature and their shapes are not intended to illustrate the actual shape of a region of a device and are not intended to be limiting. Additionally, as those skilled in the art would realize, the described embodiments may be modified in various different ways, all without departing from the spirit or scope of the present disclosure.

In the detailed description, for the purposes of explanation, numerous specific details are set forth to provide a thorough understanding of various embodiments. It is apparent, however, that various embodiments may be practiced without these specific details or with one or more equivalent arrangements. In other instances, well-known structures and devices are shown in block diagram form to avoid unnecessarily obscuring various embodiments.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or intervening layers, regions, or components may be present. However, “directly connected/directly coupled,” or “directly on,” refers to one component directly connecting or coupling another component, or being on another component, without an intermediate component. In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components such as “between,” “immediately between” or “adjacent to” and “directly adjacent to” may be construed similarly. In addition, it will also be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expression such as “at least one of A and B” and “at least one of A or B” may include A, B, or A and B. As used herein, “or” generally means “and/or,” and the term “and/or” includes any and all combinations of one or more of the associated listed items. For example, the expression such as “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section.

Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

The terminology used herein is for the purpose of describing particular embodiments only and is not intended to be limiting of the present disclosure. As used herein, the singular forms “a” and “an” are intended to include the plural forms as well, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the term “substantially,” “about,” “approximately,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

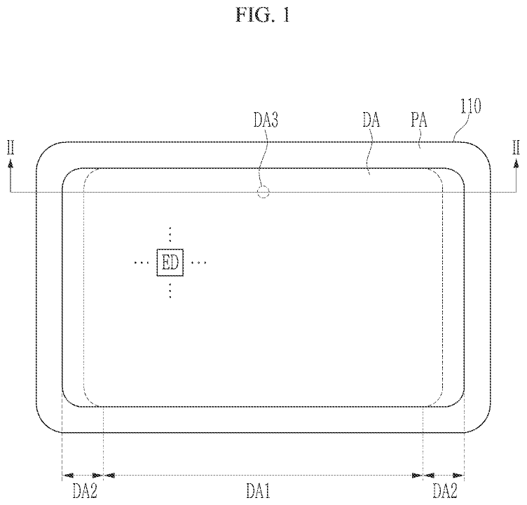

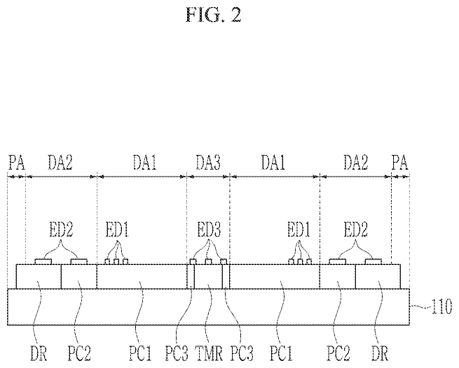

First, a display device according to one or more embodiments will be described with reference to FIG. 1 and FIG. 2.

FIG. 1 illustrates a schematic top plan view of a display device according to one or more embodiments, and FIG. 2 illustrates a cross-sectional view taken along the line Il-Il of FIG. 1.

As shown in FIG. 1 and FIG. 2, a display device according to one or more embodiments includes a substrate 110, and a light-emitting element ED positioned on the substrate 110.

The substrate 110 includes a display area DA, and a peripheral area PA adjacent to the display area DA.

The display area DA may be generally positioned at a central portion of the display device, may have an approximately quadrangular shape, and each corner thereof may have a round shape. However, the shape of the display area DA and the shape of the corner are not limited thereto, and may be variously changed. The display area DA may include a first display area DA1, a second display area DA2, and a third display area DA3. The first display area DA1 may be positioned at a central portion of the display area DA. The second display area DA2 may be positioned to be adjacent to the first display area DA1, and may be positioned outside the first display area DA1. The second display area DA2 may be positioned at both sides of the first display area DA1, for example, left and right sides. However, this is only an example, and the positions of the first display area DA1 and the second display area DA2 may be variously changed. For example, the first display area DA1 may have a substantially quadrangular shape, and the second display area DA2 may be positioned to surround all four corners of the first display area DA1. The third display area DA3 may be positioned within the first display area DA1. That is, the third display area DA3 may be surrounded by the first display area DA1 (e.g., surrounded in plan view). For example, the third display area DA3 may be positioned to be adjacent to an upper edge of the first display area DA1, and may be positioned generally at a center between a left edge and a right edge of the first display area DA1. However, this is only an example, and the position of the third display area DA3 may be variously changed. For example, the third display area DA3 may be positioned adjacent to the upper edge of the first display area DA1 and adjacent to the left or right edge thereof.

The peripheral area PA may have a shape surrounding the display area DA (e.g., surrounding in plan view). The peripheral area PA is an area in which no image is displayed, and may be positioned at an outer portion of the display device.

The light-emitting element ED may be positioned on the display area DA of the substrate 110. The light-emitting element ED may emit light (e.g., predetermined light). For example, the light-emitting element ED may emit light, such as red, green, blue, and/or white. The display device may display an image (e.g., a predetermined image) through light emitted from the light-emitting elements ED. The light-emitting element ED may include a first light-emitting element ED1 positioned in the first display area DA1, a second light-emitting element ED2 positioned in the second display area DA2, and a third light-emitting element ED3 positioned in the third display area DA3.

The display device according to one or more embodiments may include a plurality of first light-emitting elements ED1, a plurality of second light-emitting elements ED2, and a plurality of third light-emitting elements ED3. The plurality of first light-emitting elements ED1 may be located in a row direction and a column direction in the first display area DA1, the plurality of second light-emitting elements ED2 may be located in a row direction and a column direction in the second display area DA2, and the plurality of third light-emitting elements ED3 may be located in a row direction and a column direction in the third display area DA3.

A size of the first light-emitting element ED1, a size of the second light-emitting element ED2, and a size of the third light-emitting element ED3 may be the same or different. For example, the sizes of the second light-emitting element ED2 and the third light-emitting element ED3 may be larger than the size of the first light-emitting element ED1.

The number of the first light-emitting elements ED1 per unit area, the number of the second light-emitting elements ED2 per unit area, and the number of the third light-emitting elements ED3 per unit area may be the same or different. For example, the number of the second light-emitting elements ED2 per unit area and the number of the third light-emitting elements ED3 per unit area may be less than the number of the first light-emitting elements ED1 per unit area.

A resolution of the first display area DA1, a resolution of the second display area DA2, and a resolution of the third display area DA3 may be the same or different. For example, the resolution of the first display area DA1 may be higher than the resolution of the second display area DA2 and the resolution of the third display area DA3. The disposition shapes and sizes of the first light-emitting element ED1, the second light-emitting element ED2, and the third light-emitting element ED3, and the resolutions of the first display area DA1 and the second display area DA2 are not limited thereto, and may be variously changed.

The display device according to one or more embodiments may further include pixel circuit parts PC1, PC2, and PC3 positioned on the substrate 110. The pixel circuit parts PC1, PC2, and PC3 may include a first pixel circuit part PC1, a second pixel circuit part PC2, and a third pixel circuit part PC3. The display device according to one or more embodiments may include a plurality of first pixel circuit parts PC1, a plurality of second pixel circuit parts PC2, and a plurality of third pixel circuit parts PC3.

The first pixel circuit part PC1 represents an area in which the plurality of first pixel circuit parts PC1 are substantially arranged along a row direction and a column direction, the second pixel circuit part PC2 represents an area in which the plurality of second pixel circuit parts PC2 are substantially arranged along a row direction and a column direction, and the third pixel circuit part PC3 represents an area in which the plurality of third pixel circuit parts PC3 are substantially located along a row direction and a column direction. The arrangement form of the plurality of pixel circuit parts PC1, PC2, and PC3 is not particularly limited, and the plurality of pixel circuit parts PC1, PC2, and PC3 may be variously arranged.

The first pixel circuit part PC1 may be positioned in the first display area DA1, the second pixel circuit part PC2 may be positioned in the second display area DA2, and the third pixel circuit part PC3 may be positioned in the third display area DA3. Each of the pixel circuit parts PC1, PC2, and PC3 may be connected to at least one light-emitting element ED1, ED2, or ED3. The first pixel circuit part PC1 may be connected to the first light-emitting element ED1, the second pixel circuit part PC2 may be connected to the second light-emitting element ED2, and the third pixel circuit part PC3 may be connected to the third light-emitting element ED3.

A size of one first pixel circuit part PC1, a size of one second pixel circuit part PC2, and a size of one third pixel circuit part PC3 may be the same or different. For example, the size of one second pixel circuit part PC2 and the size of one third pixel circuit part PC3 may be larger than the size of one first pixel circuit part PC1. In addition, the structure of the first pixel circuit part PC1, the structure of the second pixel circuit part PC2, and the structure of the third pixel circuit part PC3 may be different.

The third pixel circuit part PC3 may be positioned at an edge of the third display area DA3. The third pixel circuit part PC3 may be positioned to be adjacent to the first display area DA1. In one or more other embodiments, the third pixel circuit part PC3 may be positioned in the first display area DA1, in which case the third pixel circuit part PC3 is positioned at an edge of the first display area DA1 so as to be adjacent to the third display area DA3.

The third display area DA3 may include a transmissive area TMR. The transmissive area TMR may be positioned at a central portion of the third display area DA3. Various electronic modules may be positioned in a portion overlapping the transmissive area TMR. For example, the electronic module may be a camera, a speaker, or a sensor sensing light or heat. The third pixel circuit part PC3 might not overlap these electronic modules. That is, the third pixel circuit part PC3 might not be positioned in the transmissive area TMR. The third light-emitting element ED3 connected to the third pixel circuit part PC3 may also be positioned in the transmissive area TMR.

The display device according to one or more embodiments may further include a driving circuit part DR positioned on the substrate 110. The driving circuit part DR may include a plurality of drivers and signal wires. For example, the driving circuit part DR may include a scan driver, a data driver, a driving voltage supplying line, a common voltage supplying line, and a signal transmitting wire connected thereto. The scan driver generates a scan signal to transmit it to the pixel circuit parts PC1, PC2, and PC3 through a scan line. The data driver generates a data signal to transmit it to the pixel circuit parts PC1, PC2, and PC3 through a data line. The driving voltage supplying line transmits a driving voltage to the pixel circuit parts PC1, PC2, and PC3. The common voltage supplying line transmits a common voltage to one electrode of the light-emitting elements ED1, ED2, and ED3. At least a portion of the driving circuit part DR may be positioned in the second display area DA2, and the remaining portion thereof may be positioned in the peripheral area PA.

In the first display area DA1, the first pixel circuit part PC1 may be electrically connected to the first light-emitting element ED1 located on the first pixel circuit part PC1. In this case, the light-emitting area of the first light-emitting element ED1 may overlap the first pixel circuit part PC1 connected thereto. The first display area DA1 is an area in which light is emitted by the first light-emitting element ED1.

In the second display area DA2, the second pixel circuit part PC2 may be electrically connected to the second light-emitting element ED2 spaced apart from each other by a distance (e.g., a predetermined distance). In this case, the light-emitting area of the second light-emitting element ED2 might not overlap the second pixel circuit part PC2 connected thereto. The light-emitting area of the second light-emitting element ED2 may overlap the driving circuit part DR. A light-emitting area of a portion of the second light-emitting element ED2 may overlap the second pixel circuit part PC2 connected thereto. The second display area DA2 is an area in which light is emitted by the second light-emitting element ED2.

In the third display area DA3, the third pixel circuit part PC3 may be electrically connected to the third light-emitting element ED3 spaced apart from each other by a distance (e.g., a predetermined distance). In this case, the light-emitting area of the third light-emitting element ED3 might not overlap the third pixel circuit part PC3 connected thereto. The light-emitting area of the third light-emitting element ED3 may overlap the transmissive area TMR. A light-emitting area of a portion of the third light-emitting element ED3 may overlap the third pixel circuit part PC3 connected thereto. The third display area DA3 is an area in which light is emitted by the third light-emitting element ED3.

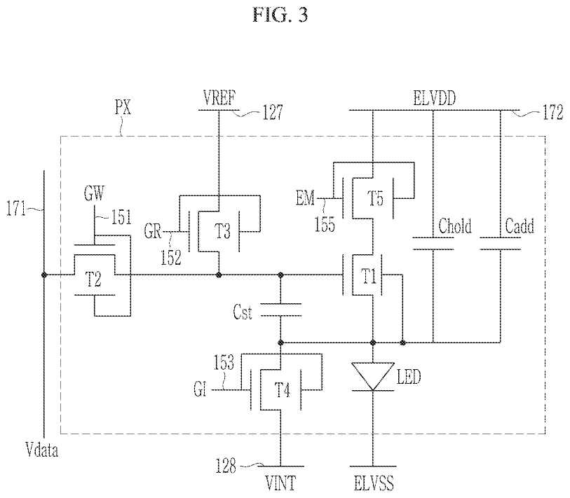

Hereinafter, one pixel of a display device according to one or more embodiments will be described with reference to FIG. 3.

FIG. 3 illustrates a circuit diagram of one pixel of a display device according to one or more embodiments.

As shown in FIG. 3, a display device according to one or more embodiments includes a plurality of pixels PX capable of displaying an image, and a plurality of signal lines 127, 128, 151, 152, 153, 155, 171, and 172. One pixel PX includes a plurality of transistors T1, T2, T3, T4, and T5 connected to the plurality of signal lines 127, 128, 151, 152, 153, 155, 171, and 172, a storage capacitor Cst, a hold capacitor Chold, an additional capacitor Cadd, and a light-emitting diode LED. Here, the transistors and the capacitors excluding the light-emitting diode LED may configure a pixel circuit part. One pixel PX may include a pixel circuit part and a light-emitting element.

A plurality of transistors T1, T2, T3, T4, and T5 may all be n-type transistors. The n-type transistor may be turned on when a relatively high voltage of a gate electrode is applied. The plurality of transistors T1, T2, T3, T4, and T5 may be oxide transistors including an oxide semiconductor.

The plurality of signal lines 127, 128, 151, 152, 153, 155, 171, and 172 are connected to one pixel PX. The plurality of wires includes a reference voltage line 127, an initialization voltage line 128, a first scan line 151, a second scan line 152, a first control line 153, a light-emitting control line 155, a data line 171, and a driving voltage line 172. Additionally, a common voltage line that transmits a driving low voltage ELVSS may be connected to one side of the light-emitting diode LED.

The first scan line 151 transmits a first scan signal GW to the second transistor T2, and the second scan line 152 transmits a second scan signal GR to the third transistor T3. The first control line 153 transmits a first control signal GI to the fourth transistor T4, and the light-emitting control line 155 transmits a light-emitting control signal EM to the fifth transistor T5.

The data line 171 is a line that transmits a data voltage Vdata generated by a data driver, and thus, as an amount of an emission current transmitted to the light-emitting diode LED is changed, and as luminance emitted by the light-emitting diode LED may also be changed. The driving voltage line 172 may transmit a driving voltage ELVDD. The reference voltage line 127 may transmit a reference voltage VREF, and the initialization voltage line 128 may transmit an initialization voltage VINT. The driving voltage ELVDD, the reference voltage VREF, and the initialization voltage VINT may be substantially constant voltages.

The driving transistor T1 (also referred to as a first transistor) is an n-type transistor, and has an oxide semiconductor as a semiconductor layer. The driving transistor T1 adjusts the amount of the light-emitting current outputted to one electrode (e.g., an anode) of the light-emitting diode LED according to a voltage of a first gate electrode of the driving transistor T1 (e.g., a voltage stored in the storage capacitor Cst). Because brightness of the light-emitting diode LED is adjusted according to the amount of the emission current outputted to one electrode of the light-emitting diode LED, light emission luminance of the light-emitting diode LED may be adjusted according to the data voltage Vdata applied to the pixel. For this purpose, a first electrode of the driving transistor T1 is located to receive the driving voltage ELVDD, and is connected to the driving voltage line 172 via the fifth transistor T5. Meanwhile, a second electrode of the driving transistor T1 outputs the light-emitting current to the light-emitting diode LED, and is connected to one electrode of the light-emitting diode LED. The data voltage Vdata may be applied to the first gate electrode of the driving transistor T1 through the second transistor T2. Meanwhile, the first gate electrode of the driving transistor T1 is connected to one electrode of the storage capacitor Cst (hereinafter referred to as a ‘second storage electrode’). Accordingly, a voltage of the first gate electrode of the driving transistor T1 is changed according to a voltage stored in the storage capacitor Cst, and a light-emitting current outputted from the driving transistor T1 is changed.

The storage capacitor Cst serves to maintain the voltage of the first gate electrode of the driving transistor T1 constant for one frame. Meanwhile, the first gate electrode of the driving transistor T1 may also be connected to the third transistor T3 to be initialized by receiving the reference voltage VREF. The driving transistor T1 may have a dual-gate structure, and may further include a second gate electrode overlapping a channel positioned on a semiconductor layer. The second gate electrode is connected to the second electrode of the driving transistor T1, one electrode (e.g., the anode) of the light-emitting diode LED, to the other end (hereinafter referred to as a ‘first storage electrode’) of the storage capacitor Cst, and to the second electrode of the fourth transistor T4. A second gate electrode of the driving transistor T2 is connected to one electrode (e.g., the anode) of the light-emitting diode LED so that the characteristic of the driving transistor T1 may be maintained without being changed during a light-emitting period.

The second transistor T2 is an n-type transistor, and has an oxide semiconductor as a semiconductor layer. The second transistor T2 is a transistor that allows the data voltage Vdata to be received into the pixel. The second transistor T2 may have a dual-gate structure. A first gate electrode and the second gate electrode of the second transistor T2 may be connected to the first scan line 151 to receive the first scan signal GW. A first electrode of the second transistor T2 is connected to the data line 171, and a second electrode of the second transistor T2 is connected to the first gate electrode of the driving transistor T1, to a second electrode of the third transistor T3, and to the second storage electrode of the storage capacitor Cst. When the second transistor T2 is turned on by a positive voltage of the first scan signal GW transmitted through the first scan line 151, the data voltage Vdata transmitted through the data line 171 is transmitted to the driving gate electrode of the driving transistor T1, and in this case, the data voltage Vdata is stored in the second storage electrode of the storage capacitor Cst.

The third transistor T3 is an n-type transistor, and has an oxide semiconductor as a semiconductor layer. The third transistor T3 serves to transmit the reference voltage VREF to the first gate electrode of the driving transistor T1 and to the second storage electrode of the storage capacitor Cst. The third transistor T3 may have a dual-gate structure. A first gate electrode and a second gate electrode of the third transistor T3 may be connected to the second scan line 152 to receive the second scan signal GR. A first electrode of the third transistor T3 is connected to the reference voltage line 127. The second electrode of the third transistor T3 is connected to the second storage electrode of the storage capacitor Cst, to the driving gate electrode of the driving transistor T1, and to the second electrode of the second transistor T2. The third transistor T3 is turned on by a positive voltage of the second scan signal GR received through the second scan line 152, and in this case, the third transistor T3 transmits the reference voltage VREF to the gate electrode of the driving transistor T1 and to the second storage electrode of the storage capacitor Cst.

The fourth transistor T4 is an n-type transistor, and has an oxide semiconductor as a semiconductor layer. The fourth transistor T4 may be an initialization transistor that initializes one electrode (e.g., the anode) of the light-emitting diode LED. When the fourth transistor T4 initializes one electrode (e.g., the anode) of the light-emitting diode LED, the fourth transistor T4 may also initialize the second gate electrode of the driving transistor T1 and the first storage electrode of the storage capacitor Cst. The fourth transistor T4 may have a dual-gate structure. A first gate electrode and a second gate electrode of the fourth transistor T4 may be connected to the first control line 153 to receive the first control signal GI. A second electrode of the fourth transistor T4 is connected to one electrode of the light-emitting diode LED, to the second gate electrode of the driving transistor T1, and to the first storage electrode of the storage capacitor Cst, and a first electrode of the fourth transistor T4 is connected to the initialization voltage line 128. When the fourth transistor T4 is turned on by a positive voltage of the first control signal GI applied to the first control line 153, the fourth transistor T4 applies the initialization voltage VINT to one electrode of the light-emitting diode LED, to an overlapping electrode (e.g., the second driving gate electrode) of the driving transistor T1, and to the first storage electrode of the storage capacitor Cst to initialize them.

The fifth transistor T5 is an n-type transistor, and has an oxide semiconductor as a semiconductor layer. The fifth transistor T5 serves to transmit the driving voltage ELVDD to the driving transistor T1. The fifth transistor T5 may have a dual-gate structure. A first gate electrode and a second gate electrode of the fifth transistor T5 may be connected to the light-emitting control line 155 to receive the light-emitting control signal EM. A first electrode of the fifth transistor T5 is connected to the driving voltage line 172, and a second electrode of the fifth transistor T5 is connected to the first electrode of the driving transistor T1. When the fifth transistor T5 is turned on by a positive voltage of the light-emitting control signal EM applied to the light-emitting control line 155, the driving voltage ELVDD is applied to the first electrode of the driving transistor T1.

It has been described above that the plurality of transistors T1, T2, T3, T4, and T5 are formed of an n-type transistor including an oxide semiconductor, but the present disclosure is not limited thereto. One or more of the transistors T1, T2, T3, T4, and T5 may include a silicon semiconductor.

The first storage electrode of the storage capacitor Cst is connected to the second electrode of the fourth transistor T4, to the second gate electrode and the second electrode of the driving transistor T1, and to one electrode (e.g., the anode) of the light-emitting diode LED, and the second storage electrode thereof is connected to the first gate electrode of the driving transistor T1, to the second electrode of the third transistor T3, and to the second electrode of the second transistor T2. The storage capacitor Cst serves to maintain the voltage of the driving gate electrode of the driving transistor T1 substantially constant for one frame.

First electrodes of the hold capacitor Chold and the additional capacitor Cadd are connected to the driving voltage line 172, and second electrodes of the hold capacitor Chold and the additional capacitor Cadd are connected to the second gate electrode of, and to the second electrode of, the driving transistor T1, to one electrode (e.g., the anode) of the light-emitting diode LED, to the second electrode of the fourth transistor T4, and to the first storage electrode of the storage capacitor Cst. The hold capacitor Chold and the additional capacitor Cadd serve to maintain the voltage of the second gate electrode of the driving transistor T1 and one electrode (e.g., the anode) of the light-emitting diode LED substantially constant (e.g., during the light-emitting period).

A pixel PX positioned in the first display area DA1, a pixel PX positioned in the second display area DA2, and a pixel PX positioned in the third display area DA3 of the display device according to one or more embodiments may all have the structure of the pixel circuit part described in FIG. 3. However, it has been described in FIG. 3 that one pixel PX includes five transistors T1, T2, T3, T4, and T5 and three capacitors Cst, Chold, and Cadd, but is not limited thereto, and may be variously changed. The number of the transistors and the number of the capacitors included in one pixel PX of the display device according to one or more embodiments and their connection relationship may be variously changed.

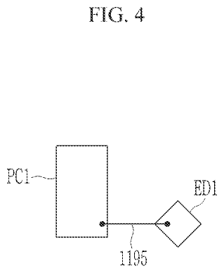

Hereinafter, a pixel positioned in the first display area DA1, a pixel positioned in the second display area DA2, and a pixel positioned in the third display area DA3 of the display device according to one or more embodiments will be described with reference to FIG. 4 to FIG. 9.

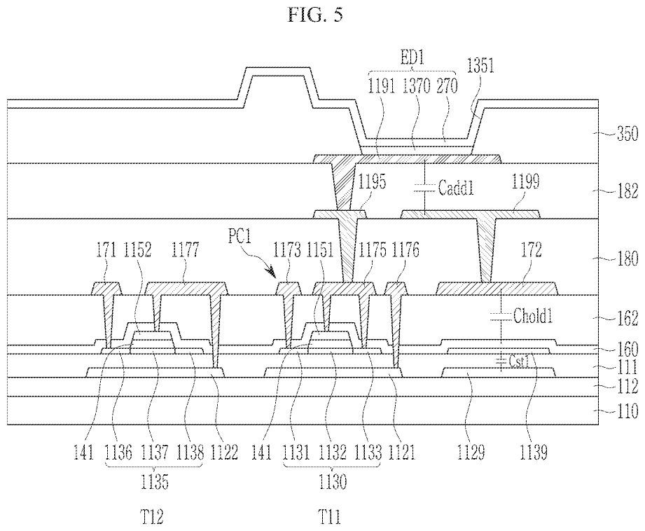

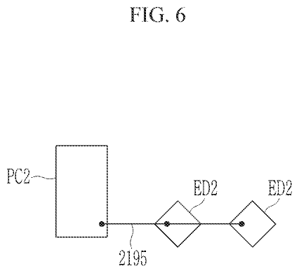

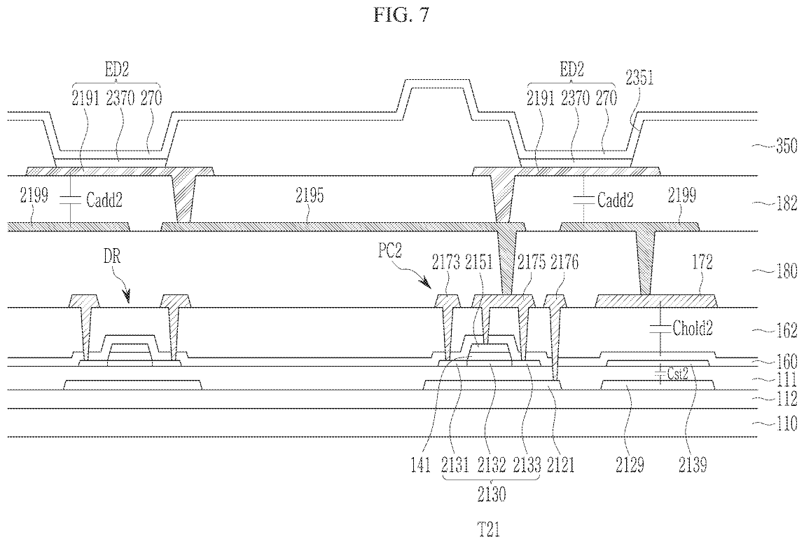

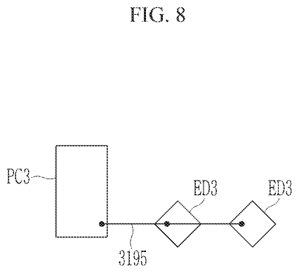

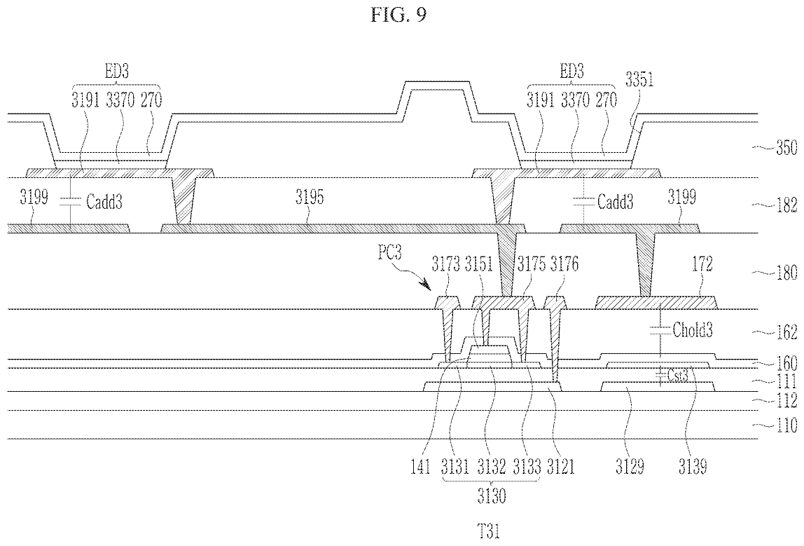

FIG. 4 illustrates a schematic view of a pixel positioned in a first display area of a display device according to one or more embodiments, and FIG. 5 illustrates a cross-sectional view of a pixel positioned in a first display area of a display device according to one or more embodiments. FIG. 6 illustrates a schematic view of a pixel positioned in a second display area of a display device according to one or more embodiments, and FIG. 7 illustrates a cross-sectional view of a pixel positioned in a second display area of a display device according to one or more embodiments. FIG. 8 illustrates a schematic view of a pixel positioned in a third display area of a display device according to one or more embodiments, and FIG. 9 illustrates a cross-sectional view of a pixel positioned in a third display area of a display device according to one or more embodiments.

First, as shown in FIG. 4 and FIG. 5, according to one or more embodiments, the pixel positioned in the first display area of the display device includes the substrate 110, the first pixel circuit part PC1 positioned on the substrate 110, and the first light-emitting element ED1 connected to the first pixel circuit part PC1. In this case, one first pixel circuit part PC1 may be connected to one first light-emitting element ED1. As described above, the first pixel circuit part PC1 may include, for example, five transistors and three capacitors. FIG. 5 illustrates a cross-sectional view of, as some constituent elements of the five transistors and the three capacitors, a driving transistor T11, a second transistor T12, a storage capacitor Cst1, a hold capacitor Chold1, and an additional capacitor Cadd1.

The substrate 110 may include at least one of polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, cellulose triacetate, and/or cellulose acetate propionate. The substrate 110 may be a rigid substrate, or a flexible substrate that is bendable, foldable, or rollable. The substrate 110 may be single-layered or multi-layered. The substrate 110 may be one in which at least one base layer and at least one inorganic layer, which include polymer resins sequentially stacked, are alternately stacked.

A barrier layer 112 may be positioned on the substrate 110. The barrier layer 112 may include an inorganic insulating material, such as a silicon nitride (SiNx), a silicon oxide (SiOx), and a silicon oxynitride (SiOxNy). The barrier layer 112 may have a single-layer or multi-layered structure of the material. In some embodiments, the barrier layer 112 may be omitted.

A first conductive layer including a first gate electrode 1121 of the driving transistor T11 of the first pixel circuit part PC1, a first gate electrode 1122 of the second transistor T12 of the first pixel circuit part PC1, and a second storage electrode 1129 of the storage capacitor Cst1 of the first pixel circuit part PC1 may be positioned on the barrier layer 112. The first gate electrode 1121 of the driving transistor T11 and the second storage electrode 1129 of the storage capacitor Cst1 may be electrically connected to each other. In addition, the first gate electrode 1121 of the driving transistor T11 and the second storage electrode 1129 of the storage capacitor Cst1 may be directly connected. The first conductive layer may have a single-layered or multi-layered structure. The first conductive layer may include metal materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu).

A buffer layer 111 may be positioned on the first conductive layer and on the barrier layer 112. The buffer layer 111 may have a single-layered or multi-layered structure. The buffer layer 111 may include an inorganic insulating material, such as a silicon nitride (SiNx), a silicon oxide (SiOx), and a silicon oxide (SiOxNy), or an organic insulating material. In some embodiments, the buffer layer 210 may be omitted.

A semiconductor layer including a semiconductor 1130 of the driving transistor T11 of the first pixel circuit part PC1, a semiconductor 1135 of the second transistor T12 of the first pixel circuit part PC1, and a first storage electrode 1139 of the storage capacitor Cst1 of the first pixel circuit part PC1 may be positioned on the buffer layer 111. The semiconductor 1130 of the driving transistor T11 may overlap the first gate electrode 1121 of the driving transistor T11. The semiconductor 1130 of the driving transistor T1 may include a first area 1131, a channel 1132, and a second area 1133. The first area 1131 and the second area 1133 may be positioned at respective sides of the channel 1132 of the semiconductor 1130 of the driving transistor T11. The semiconductor 1135 of the second transistor T12 may overlap the first gate electrode 1122 of the second transistor T12. The semiconductor 1135 of the second transistor T12 may include a first area 1136, a channel 1137, and a second area 1138. The first area 1136 and the second area 1138 may be positioned at respective sides of the channel 1137 of the semiconductor 1135 of the second transistor T12. The first storage electrode 1139 of the storage capacitor Cst1 may overlap the second storage electrode 1129. The first storage electrode 1139 may be electrically connected to the second area 1133 of the semiconductor 1130 of the driving transistor T11. The first storage electrode 1139 may be directly connected to the second area 1133 of the semiconductor 1130 of the driving transistor T11.

The semiconductor layer may be made of an oxide semiconductor. The oxide semiconductor may include at least one of a primary metal oxide, such as an indium (In) oxide, a tin (Sn) oxide, or a zinc (Zn) oxide; a binary metal oxide, such as an In—Zn-based oxide, a Sn—Zn-based oxide, an Al—Zn-based oxide, a Zn—Mg-based oxide, a Sn—Mg-based oxide, an In—Mg-based oxide, or an In—Ga-based oxide; a ternary metal oxides, such as an In—Ga—Zn-based oxide, an In—Al—Zn-based oxide, an In—Sn—Zn-based oxide, a Sn—Ga—Zn-based oxide, an Al—Ga—Zn-based oxide, a Sn—Al—Zn-based oxide, an In—Hf—Zn-based oxide, an In—La—Zn-based oxide, an In—Ce—Zn-based oxide, an In—Pr—Zn-based oxide, an In—Nd—Zn-based oxide, an In—Sm—Zn-based oxide, an In—Eu—Zn-based oxide, an In—Gd—Zn-based oxide, an In—Tb—Zn-based oxide, an In—Dy—Zn-based oxide, an In—Ho—Zn-based oxide, an In—Er—Zn-based oxide, an In—Tm—Zn-base oxide, an In—Yb—Zn-based oxide, or an In—Lu—Zn-based oxide; and a quaternary metal oxide, such as an In—Sn—Ga—Zn-based oxide, an In—Hf—Ga—Zn-based oxide, an In—Al—Ga—Zn-based oxide, an In—Sn—Al—Zn-based oxide, an In—Sn—Hf—Zn-based oxide, and/or an In—Hf—Al—Zn-based oxide. For example, the semiconductor layer may include an indium-gallium-zinc oxide (IGZO) among the In—Ga—Zn-based oxide. However, the material of the semiconductor layer is not limited thereto, and may be an amorphous silicon or a polysilicon.

The gate-insulating film 141 may be positioned on the semiconductor layer. The gate-insulating film 141 may be positioned on the semiconductor 1130 of the driving transistor T11, and on the semiconductor 1135 of the second transistor T12, of the first pixel circuit part PC1. The gate-insulating film 141 may overlap the channel 1132 of the semiconductor 1130 of the driving transistor T11, and might not overlap the first area 1131 and the second area 1133 of the driving transistor T11. The gate-insulating film 141 may overlap the channel 1137 of the semiconductor 1135 of the second transistor T12, and might not overlap the first area 1136 and the second area 1138 of the second transistor T12. However, the present disclosure is not limited thereto, and the gate-insulating film 141 may be entirely formed on the semiconductor layer and the buffer layer 111. The gate-insulating film 141 may have a single-layered or multi-layered structure. The gate-insulating film 141 may include an inorganic insulation material, such as a silicon nitride (SiNx), a silicon oxide (SiOx), and a silicon oxynitride (SiOxNy).

A second conductive layer including a second gate electrode 1151 of the driving transistor T11, and a second gate electrode 1152 of the second transistor T12, of the first pixel circuit part PC1 may be positioned on the gate-insulating film 141. The second gate electrode 1151 of the driving transistor T11 may overlap the channel 1132 of the semiconductor 1130. The second gate electrode 1152 of the second transistor T12 may overlap the channel 1137 of the semiconductor 1135. The second conductive layer may have a single-layered or multi-layered structure. The second conductive layer may include metal materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu).

After forming the second conductive layer, a doping process or plasma treatment may be performed. A portion of the semiconductor layer that is covered by the second conductive layer is not doped or plasma-treated, and a portion of the semiconductor layer that is not covered by the second conductive layer is doped or plasma-treated to have characteristics similar to a conductor. That is, the first area 1131 and the second area 1133 of the semiconductor 1130 of the driving transistor T11, the first area 1136 and the second area 1138 of the semiconductor 1135 of the second transistor T12, and the first storage electrode 1139 may have conductivity. The doping process of the semiconductor layer may be performed with an n-type dopant, and the transistors included in the first pixel circuit part PC1 may have an n-type transistor characteristic.

A first interlayer insulating film 160 may be positioned on the second conductive layer, on the semiconductor layer, and on the buffer layer 111. A second interlayer insulating film 162 may be positioned on the first interlayer insulating film 160. The first interlayer insulating film 160 and the second interlayer insulating film 162 may have a single-layered or multi-layered structure. The first interlayer insulating film 160 and the second interlayer insulating film 162 may include an inorganic insulating material, such as a silicon nitride (SiNx), a silicon oxide (SiOx), or a silicon oxide (SiOxNy), or an organic insulating material. For example, the first interlayer insulating film 160 may be made of an inorganic insulating material, and the second interlayer insulating film 162 may be made of an organic insulating material. In some cases, at least one of the first interlayer insulating film 160 and/or the second interlayer insulating film 162 may be omitted.

A third conductive layer including a source electrode 1173 and a drain electrode 1175 of the driving transistor T11 of the first pixel circuit part PC1, a first connection electrode 1176, a second connection electrode 1177, the data line 171, and the driving voltage line 172 may be positioned on the second interlayer insulating film 162.

The source electrode 1173 of the driving transistor T11 may be connected to the first area 1131 of the semiconductor 1130 through an opening formed in the first and second interlayer insulating films 160 and 162. The drain electrode 1175 of the driving transistor T11 may be connected to the second area 1133 of the semiconductor 1130 through an opening formed in the first and second interlayer insulating films 160 and 162, and may also be connected to the second gate electrode 1151. The first connection electrode 1176 may be connected to the first gate electrode 1121 of the driving transistor T11 through an opening formed in the first and second interlayer insulating films 160 and 162 and in the buffer layer 111. In one or more embodiments, the first connection electrode 1176 may be electrically connected to the second area 1138 of the semiconductor 1135 of the second transistor T12. Accordingly, the first gate electrode 1121 of the driving transistor T11 and the second area 1138 of the semiconductor 1135 of the second transistor T12 may be connected by the first connection electrode 1176.

The second connection electrode 1177 may be connected to the first gate electrode 1122 of the second transistor T12 through the opening formed in the first and second interlayer insulating films 160 and 162 and in the buffer layer 111, and may be connected to the second gate electrode 1152 of the second transistor T12 through an opening formed in the first and second interlayer insulating films 160 and 162. Accordingly, the first gate electrode 1122 and the second gate electrode 1152 of the second transistor T12 may be connected by the second connection electrode 1177. The data line 171 may be connected to the first area 1136 of the semiconductor 1135 of the second transistor T12 through the opening formed in the first and second interlayer insulating films 160 and 162.

The driving voltage line 172 may overlap the first storage electrode 1139 of the storage capacitor Cst1. The driving voltage line 172 to which the driving voltage ELVDD is applied and the first storage electrode 1139 may overlap each other to form the hold capacitor Chold1. In this case, the driving voltage line 172 may be the first electrode of the hold capacitor Chold1, and the first storage electrode 1139 may be the second electrode of the hold capacitor Chold1. In one or more embodiments, the driving voltage line 172 has been described as being positioned in the third conductive layer, but is not limited thereto. The driving voltage line 172 may be positioned in another layer, for example, in the second conductive layer.

The third conductive layer may have a single-layered or multi-layered structure. The third conductive layer may include metal materials, such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu). The third conductive layer may have a triple-filmed structure including: a lower film including a refractory metal, such as molybdenum, chromium, tantalum, and titanium or an alloy thereof; an interlayer film including a low resistivity aluminum-based metal, a silver-based metal, or a copper-based metal; and an upper film including a refractory metal, such as molybdenum, chromium, tantalum, and titanium.

A first passivation film 180 may be positioned on the third conductive layer. The first passivation film 180 may include an organic insulating material, such as a general purpose polymer, such as polymethylmethacrylate (PMMA) or polystyrene (PS), a polymer derivative having a phenolic group, an imide-based polymer, a polyimide, an acryl-based polymer, and/or a siloxane-based polymer.

A fourth conductive layer including a first extension electrode 1195 and an additional capacitor electrode 1199 may be positioned on the first passivation film 180. The first extension electrode 1195 may be connected to the drain electrode 1175 of the driving transistor T11 of the first pixel circuit part PC1 through an opening formed in the first passivation film 180. The additional capacitor electrode 1199 may be connected to the driving voltage line 172 through the opening formed in the first passivation film 180. In one or more embodiments, the additional capacitor electrode 1199 has been described as being connected to the driving voltage line 172, but is not limited thereto. The additional capacitor electrode 1199 may be connected to another wire to which a constant voltage is applied instead of the driving voltage line 172. For example, the additional capacitor electrode 1199 may be connected to a reference voltage line, an initialization voltage line, and the like. The fourth conductive layer may have a single-layered or multi-layered structure. The fourth conductive layer may include a transparent conductive oxide (TCO), such as an indium tin oxide (ITO) or an indium zinc oxide (IZO).

A second passivation film 182 may be positioned on the fourth conductive layer and the first passivation film 180. The second passivation film 182 may include an organic insulating material, such as a general purpose polymer, such as poly(methyl methacrylate) (PMMA) or polystyrene (PS), a polymer derivative having a phenolic group, an imide-based polymer, a polyimide, an acryl-based polymer, and/or a siloxane-based polymer.

The first light-emitting element ED1 connected to the first pixel circuit part PC1 may be positioned on the second passivation film 182. The first light-emitting element ED1 may be connected to the first pixel circuit part PC1 through the first extension electrode 1195. The first light-emitting element ED1 may include a first pixel electrode 1191, a first light-emitting layer 1370, and a common electrode 270.

The first pixel electrode 1191 of the first light-emitting element ED1 may be positioned on the second passivation film 182. The first pixel electrode 1191 may be connected to the first extension electrode 1195 through an opening formed in the second passivation film 182. Accordingly, the first pixel electrode 1191 may be connected to the drain electrode 1175 of the driving transistor T11 of the first pixel circuit part PC1 through the first extension electrode 1195.

The first pixel electrode 1191 may overlap the additional capacitor electrode 1199. The additional capacitor Cadd1 may be formed by overlapping the first pixel electrode 1191 and the additional capacitor electrode 1199 to which the driving voltage ELVDD is applied. In this case, the additional capacitor electrode 1199 may be the first electrode of the additional capacitor Cadd1, and the first pixel electrode 1191 may be the second electrode of the additional capacitor Cadd1. As such, the additional capacitor electrode 1199 is positioned to overlap the first pixel electrode 1191 in the fourth conductive layer in which the first extension electrode 1195 is formed, so that additional capacitance may be secured without adding a process. That is, it is possible to improve the capacitance without an increase in time and cost, so that the display device according to one or more embodiments may be stably driven.

A partition wall 350 may be positioned on the first pixel electrode 1191 of the first light-emitting element ED1. The partition wall 350 is also referred to as a pixel-defining layer (PDL), and includes a pixel opening 1351 overlapping at least a portion of the first pixel electrode 1191. In this case, the pixel opening 1351 may overlap a central portion of the first pixel electrode 1191, and might not overlap an edge portion of the first pixel electrode 1191. Accordingly, a size of the pixel opening 1351 may be less than that of the first pixel electrode 1191. The partition wall 350 may be an organic insulation film containing one or more of polyimide, polyamide, an acryl resin, benzocyclobutene, and/or a phenol resin. In addition, the partition wall 350 may include an inorganic insulating material, such as a silicon nitride (SiNx), a silicon oxide (SiOx), and a silicon oxynitride (SiOxNy). In addition, the partition wall 350 may be formed of a black pixel-defining layer (BPDL) including a light-blocking material. In this case, the light-blocking material may include carbon black, carbon nanotubes, a resin or paste containing a black dye, metal particles, such as nickel, aluminum, molybdenum, and/or an alloy thereof, a metal oxide particle (for example, chromium oxide), or a metal nitride particle (for example, chromium nitride). When the partition wall 350 includes a light-blocking material, reflection of external light by metal structures located under the partition wall 350 may be reduced. However, the present disclosure is not limited thereto, and the partition wall 350 does not include a light-blocking material, but may include a light-transmitting organic insulating material.

The first light-emitting layer 1370 may be positioned within the pixel opening 1351 of the partition wall 350. The first light-emitting layer 1370 may overlap the first pixel electrode 1191. The first light-emitting layer 1370 may include an organic material that emits red, green, and blue light. The first light-emitting layer 1370 may include a low molecular weight or high molecular weight organic material. Although the first light-emitting layer 1370 is illustrated as a single layer, in reality, an auxiliary layer, such as a hole injection layer (HIL), a hole-transporting layer (HTL), an electron-transporting layer (ETL), and/or an electron injection layer (EIL) may be further positioned, respectively, at upper and lower sides of the first light-emitting layer 1370. In this case, the hole injection layer and the hole-transporting layer may be positioned at the lower side of the first light-emitting layer 1370, and the electron-transporting layer and the electron injection layer may be located at the upper side of the first light-emitting layer 1370.

The common electrode 270 may be positioned on the first light-emitting layer 1370 and the partition wall 350. The common electrode 270 may be entirely positioned in most areas on the substrate 110. The common electrode 270 is also referred to as a cathode, and may include a reflective metal including calcium (Ca), barium (Ba), magnesium (Mg), aluminum (Al), silver (Ag), platinum (Pt), palladium (Pd), gold (Au), nickel (Ni), neodymium (Nd), iridium (Ir), chromium (Cr), lithium (Li), or calcium (Ca), or a transparent conductive oxide (TCO), such as an indium tin oxide (ITO) or an indium zinc oxide (IZO).

The first pixel electrode 1191, the first light-emitting layer 1370, and the common electrode 270 may form the first light-emitting element ED1 together. In this case, the first pixel electrode 1191 may be an anode electrode, which is a hole injection electrode, and the common electrode 270 may be a cathode electrode, which is an electron injection electrode. However, the present disclosure is not limited thereto, and the anode electrode and the cathode electrode may be oppositely formed according to a driving method of the display device.

Holes and electrons are injected into the first light-emitting layer 1370 from the first pixel electrode 1191 and the common electrode 270, respectively, and excitons generated by coupling the injected holes and electrons fall from an excited state to a ground state to emit light.

In one or more embodiments, an encapsulation layer may be further located on the common electrode 270. The encapsulation layer is for protecting the first light-emitting diode ED1 from moisture or oxygen that may be introduced from the outside, and may include at least one inorganic film and at least one organic film. For example, the encapsulation layer may have a structure in which a first inorganic encapsulation layer, an organic encapsulation layer, and a second inorganic encapsulation layer are stacked. However, this is only an example, and the number of inorganic and organic films configuring the encapsulation layer may be variously changed.

Next, as shown in FIG. 6 and FIG. 7, the pixel positioned in the second display area of the display device according to one or more embodiments includes the substrate 110, the second pixel circuit part PC2 positioned on the substrate 110, and the second light-emitting element ED2 connected to the second pixel circuit part PC2. In this case, one second pixel circuit part PC2 may be connected to a plurality of second light-emitting elements ED2. As described above, the second pixel circuit part PC2 may include, for example, five transistors and three capacitors. FIG. 7 illustrates a cross-sectional view of, as some constituent elements of the five transistors and the three capacitors, a driving transistor T21, a storage capacitor Cst2, a hold capacitor Chold2, and an additional capacitor Cadd2.

The barrier layer 112 may be positioned on the substrate 110, and a first gate electrode 2121 of the driving transistor T21 of the second pixel circuit part PC2, a second storage electrode 2129 of the storage capacitor Cst2, and the like may be positioned on the barrier layer 112. The first gate electrode 2121 of the driving transistor T21 of the second pixel circuit part PC2, and the second storage electrode 2129 of the storage capacitor Cst2, may be positioned in the first conductive layer.

The buffer layer 111 may be positioned on the first conductive layer, and a semiconductor 2130 of the driving transistor T21 of the second pixel circuit part PC2, a first storage electrode 2139 of the storage capacitor Cst2, and the like may be positioned on the buffer layer 111. The semiconductor 2130 of the driving transistor T21 of the second pixel circuit part PC2, and the first storage electrode 2139 of the storage capacitor Cst2, may be positioned in the semiconductor layer. The semiconductor 2130 of the driving transistor T21 may overlap the first gate electrode 2121 of the driving transistor T21. The semiconductor 2130 of the driving transistor T21 may include a first area 2131, a channel 2132, and a second area 2133. The first area 2131 and the second area 2133 may be positioned at respective sides of the channel 2132 of the semiconductor 2130 of the driving transistor T21. The first storage electrode 2139 of the storage capacitor Cst2 may overlap the second storage electrode 2129. The first storage electrode 2139 may be electrically connected to the second area 2133 of the semiconductor 2130 of the driving transistor T21. The first storage electrode 2139 may be directly connected to the second area 2133 of the semiconductor 2130 of the driving transistor T21.

The gate-insulating film 141 may be positioned on the semiconductor layer, and a second gate electrode 2151 of the driving transistor T21 of the second pixel circuit part PC2 may be positioned on the gate-insulating film 141. The second gate electrode 2151 of the driving transistor T21 of the second pixel circuit part PC2 may be positioned in the second conductive layer. The second gate electrode 2151 of the driving transistor T21 may overlap the channel 2132 of the semiconductor 2130.

The first interlayer insulating film 160 and the second interlayer insulating film 162 may be positioned on the second conductive layer, on the semiconductor layer, and on the buffer layer 111. A source electrode 2173 and a drain electrode 2175 of the driving transistor T21 of the second pixel circuit part PC2, a connection electrode 2176, and the driving voltage line 172 may be positioned on the second interlayer insulating film 162. The source electrode 2173 and the drain electrode 2175 of the driving transistor T21 of the second pixel circuit part PC2, the connection electrode 2176, and the driving voltage line 172 may be positioned in the third conductive layer.

The source electrode 2173 of the driving transistor T21 may be connected to the first area 2131 of the semiconductor 2130 through an opening formed in the first and second interlayer insulating films 160 and 162. The drain electrode 2175 of the driving transistor T21 may be connected to the second area 2133 of the semiconductor 2130 through an opening formed in the first and second interlayer insulating films 160 and 162, and may also be connected to the second gate electrode 2151. The connection electrode 2176 may be connected to the first gate electrode 2121 of the driving transistor T21 through an opening formed in the first and second interlayer insulating films 160 and 162 and the buffer layer 111.

The driving voltage line 172 may overlap the first storage electrode 2139 of the storage capacitor Cst2. The driving voltage line 172 to which the driving voltage ELVDD is applied and the first storage electrode 2139 may overlap each other to form the hold capacitor Chold2. In this case, the driving voltage line 172 may be the first electrode of the hold capacitor Chold2, and the first storage electrode 2139 may be the second electrode of the hold capacitor Chold2.

The first passivation film 180 may be positioned on the third conductive layer, and a second extension electrode 2195 and an additional capacitor electrode 2199 may be positioned on the first passivation film 180. The second extension electrode 2195 and the additional capacitor electrode 2199 may be positioned in the fourth conductive layer. The second extension electrode 2195 may be connected to the drain electrode 2175 of the driving transistor T21 of the second pixel circuit part PC2 through an opening formed in the first passivation film 180. The additional capacitor electrode 2199 may be connected to the driving voltage line 172 through the opening formed in the first passivation film 180. In one or more embodiments, the additional capacitor electrode 2199 has been described as being connected to the driving voltage line 172, but is not limited thereto. The additional capacitor electrode 2199 may be connected to another wire to which a constant voltage is applied instead of the driving voltage line 172. For example, the additional capacitor electrode 2199 may be connected to a reference voltage line, an initialization voltage line, and the like.

The second passivation film 182 may be positioned on the fourth conductive layer and the first passivation film 180, and the second light-emitting element ED2 connected to the second pixel circuit part PC2 may be positioned on the second passivation film 182. The second light-emitting element ED2 may be connected to the second pixel circuit part PC2 through the second extension electrode 2195. The second extension electrode 2195 may extend lengthwise in a plan view, and one second extension electrode 2195 may be connected to a plurality of second light-emitting elements ED2. Accordingly, one second pixel circuit part PC2 may be connected to the plurality of second light-emitting elements ED2 through the second extension electrode 2195. For example, one second pixel circuit part PC2 may be connected to two second light-emitting parts ED2. The second light-emitting element ED2 may include a second pixel electrode 2191, a second light-emitting layer 2370, and the common electrode 270.

The second pixel electrode 2191 of the second light-emitting element ED2 may be positioned on the second passivation film 182. A plurality of second pixel electrodes 2191 may be connected to the second extension electrode 2195 through an opening formed in the second passivation film 182. Accordingly, the plurality of second pixel electrodes 2191 may be connected to the drain electrode 2175 of the driving transistor T21 of the second pixel circuit part PC2 through the second extension electrode 2195.

The second pixel electrode 2191 may overlap the additional capacitor electrode 2199. The additional capacitor Cadd2 may be formed by overlapping the second pixel electrode 2191 and the additional capacitor electrode 2199 to which the driving voltage ELVDD is applied. In this case, the additional capacitor electrode 2199 may be the first electrode of the additional capacitor Cadd2, and the second pixel electrode 2191 may be the second electrode of the additional capacitor Cadd2. As such, the additional capacitor electrode 2199 is positioned to overlap the second pixel electrode 2191 in the fourth conductive layer in which the second extension electrode 2195 is formed, so that additional capacitance may be secured without adding a process. That is, it is possible to improve the capacitance without an increase in time and cost associated with manufacturing, so that the display device according to one or more embodiments may be stably driven.

The partition wall 350 may be positioned on the second pixel electrode 2191 of the second light-emitting element ED2, and the partition wall 350 includes a pixel opening 2351 overlapping at least a portion of the second pixel electrode 2191. The second light-emitting layer 2370 may be positioned within the pixel opening 2351 of the partition wall 350. The second light-emitting layer 2370 may overlap the second pixel electrode 2191. The common electrode 270 may be positioned on the second light-emitting layer 2370 and the partition wall 350. The second pixel electrode 2191, the second light-emitting layer 2370, and the common electrode 270 may form the second light-emitting element ED2 together.

As described above, the driving circuit part DR may be positioned in the second display area of the display device. The driving circuit part DR may include a wire, an electrode, a semiconductor, and the like that are positioned in the first conductive layer, the semiconductor layer, the second conductive layer, and the third conductive layer as components. The driving circuit part DR may overlap the second light-emitting part ED2. Some of the plurality of second light-emitting elements ED2 positioned in the second display area may overlap the second pixel circuit part PC2, and some other thereof may overlap the driving circuit part DR. As such, the display area of the display device according to one or more embodiments may be further increased by allowing a screen to be displayed even in a portion in which the driving circuit part DR is positioned.

Next, as shown in FIG. 8 and FIG. 9, the pixel positioned in the third display area of the display device according to one or more embodiments includes the substrate 110, the third pixel circuit part PC3 positioned on the substrate 110, and the third light-emitting element ED3 connected to the third pixel circuit part PC3. In this case, one third pixel circuit part PC3 may be connected to a plurality of third light-emitting elements ED3. As described above, the third pixel circuit part PC3 may include, for example, five transistors and three capacitors. FIG. 9 illustrates a cross-sectional view of, as some constituent elements of the five transistors and the three capacitors, a driving transistor T31, a storage capacitor Cst3, a hold capacitor Chold3, and an additional capacitor Cadd3.

The barrier layer 112 may be positioned on the substrate 110, and a first gate electrode 3121 of the driving transistor T31 of the third pixel circuit part PC3, a second storage electrode 3129 of the storage capacitor Cst3, and the like may be positioned on the barrier layer 112. The first gate electrode 3121 of the driving transistor T31 of the third pixel circuit part PC3 and the second storage electrode 3129 of the storage capacitor Cst3 may be positioned in the first conductive layer.

The buffer layer 111 may be positioned on the first conductive layer. A semiconductor 3130 of the driving transistor T31 of the third pixel circuit part PC3, a first storage electrode 3139 of the storage capacitor Cst3, and the like may be positioned on the buffer layer 111. The semiconductor 3130 of the driving transistor T31 of the third pixel circuit part PC3 and the first storage electrode 3139 of the storage capacitor Cst3 may be positioned in the semiconductor layer. The semiconductor 3130 of the driving transistor T31 may overlap the first gate electrode 3121 of the driving transistor T31. The semiconductor 3130 of the driving transistor T31 may include a first area 3131, a channel 3132, and a second area 3133. The first area 3131 and the second area 3133 may be positioned at respective sides of the channel 3132 of the semiconductor 3130 of the driving transistor T31. The first storage electrode 3139 of the storage capacitor Cst3 may overlap the second storage electrode 3129. The first storage electrode 3139 may be electrically connected to the second area 3133 of the semiconductor 3130 of the driving transistor T31. The first storage electrode 3139 may be directly connected to the second area 3133 of the semiconductor 3130 of the driving transistor T31.

The gate-insulating film 141 may be positioned on the semiconductor layer. A second gate electrode 3151 of the driving transistor T31 of the third pixel circuit part PC3 may be positioned on the gate-insulating film 141. The second gate electrode 3151 of the driving transistor T31 of the third pixel circuit part PC3 may be positioned in the second conductive layer. The second gate electrode 3151 of the driving transistor T31 may overlap the channel 3132 of the semiconductor 3130.

The first interlayer insulating film 160 and the second interlayer insulating film 162 may be positioned on the second conductive layer, on the semiconductor layer, and on the buffer layer 111. A source electrode 3173 and a drain electrode 3175 of the driving transistor T31 of the third pixel circuit part PC3, a connection electrode 3176, and the driving voltage line 172 may be positioned on the second interlayer insulating film 162. The source electrode 3173 and the drain electrode 3175 of the driving transistor T31 of the third pixel circuit part PC3, the connection electrode 3176, and the driving voltage line 172 may be positioned in the third conductive layer.

The source electrode 3173 of the driving transistor T31 may be connected to the first area 3131 of the semiconductor 3130 through an opening formed in the first and second interlayer insulating films 160 and 162. The drain electrode 3175 of the driving transistor T31 may be connected to the second area 3133 of the semiconductor 3130 through an opening formed in the first and second interlayer insulating films 160 and 162, and may also be connected to the second gate electrode 3151. The connection electrode 3176 may be connected to the first gate electrode 3121 of the driving transistor T31 through an opening formed in the first and second interlayer insulating films 160 and 162 and the buffer layer 111.

The driving voltage line 172 may overlap the first storage electrode 3139 of the storage capacitor Cst3. The driving voltage line 172 to which the driving voltage ELVDD is applied and the first storage electrode 3139 may overlap each other to form the hold capacitor Chold3. In this case, the driving voltage line 172 may be the first electrode of the hold capacitor Chold3, and the first storage electrode 3139 may be the second electrode of the hold capacitor Chold3.

The first passivation film 180 may be positioned on the third conductive layer, and a third extension electrode 3195 and an additional capacitor electrode 3199 may be positioned on the first passivation film 180. The third extension electrode 3195 and the additional capacitor electrode 3199 may be positioned in the fourth conductive layer. The third extension electrode 3195 may be connected to the drain electrode 3175 of the driving transistor T31 of the third pixel circuit part PC3 through an opening formed in the first passivation film 180. The additional capacitor electrode 3199 may be connected to the driving voltage line 172 through the opening formed in the first passivation film 180. In one or more embodiments, the additional capacitor electrode 3199 has been described as being connected to the driving voltage line 172, but is not limited thereto. The additional capacitor electrode 3199 may be connected to another wire to which a constant voltage is applied instead of the driving voltage line 172. For example, the additional capacitor electrode 3199 may be connected to a reference voltage line, an initialization voltage line, and the like.

The second passivation film 182 may be positioned on the fourth conductive layer and the first passivation film 180. The third light-emitting element ED3 connected to the third pixel circuit part PC3 may be positioned on the second passivation film 182. The third light-emitting element ED3 may be connected to the third pixel circuit part PC3 through the third extension electrode 3195. The third extension electrode 3195 may extend long in a plan view, and one third extension electrode 3195 may be connected to a plurality of third light-emitting elements ED2. Accordingly, one third pixel circuit part PC3 may be connected to the plurality of third light-emitting elements ED3 through the third extension electrode 3195. For example, one third pixel circuit part PC3 may be connected to two third light-emitting elements ED3. The third light-emitting element ED3 may include a third pixel electrode 3191, a third light-emitting layer 3370, and the common electrode 270.

The third pixel electrode 3191 of the third light-emitting element ED3 may be positioned on the second passivation film 182. A plurality of third pixel electrodes 3191 may be connected to the third extension electrode 3195 through an opening formed in the second passivation film 182. Accordingly, the plurality of third pixel electrodes 3191 may be connected to the drain electrode 3175 of the driving transistor T31 of the third pixel circuit part PC3 through the third extension electrode 3195.

The third pixel electrode 3191 may overlap the additional capacitor electrode 3199. The additional capacitor Cadd2 may be formed by overlapping the third pixel electrode 3191 and the additional capacitor electrode 3199 to which the driving voltage ELVDD is applied. As such, the additional capacitor electrode 3199 is positioned to overlap the third pixel electrode 3191 in the fourth conductive layer in which the third extension electrode 3195 is formed, so that additional capacitance may be secured without adding a process. That is, it is possible to improve the capacitance without an increase in time and cost, so that the display device according to one or more embodiments may be stably driven.

The partition wall 350 may be positioned on the third pixel electrode 3191 of the third light-emitting element ED3, and the partition wall 350 includes a pixel opening 3351 overlapping at least a portion of the third pixel electrode 3191. The third light-emitting layer 3370 may be positioned within the pixel opening 3351 of the partition wall 350. The third light-emitting layer 3370 may overlap the third pixel electrode 3191. The common electrode 270 may be positioned on the third light-emitting layer 3370 and the partition wall 350. The third pixel electrode 3191, the third light-emitting layer 3370, and the common electrode 270 may form the third light-emitting element ED3 together.

As described above, the third display area of the display device according to one or more embodiments may include a transmissive area, and various electronic modules may be positioned in the transmissive area. For example, the electronic module may be positioned under the substrate 110. The first conductive layer, the second conductive layer, and the third conductive layer are not positioned in the transmissive area, so that transmittance of the transmissive area may be improved. Because the fourth conductive layer is made of a transparent conductive oxide, the fourth conductive layer may be positioned in the transmissive area. Accordingly, the third pixel circuit part PC3 might not be positioned in the transmissive area, and the third extension electrode 3195 and the additional capacitor Cadd3 may be positioned in the transmissive area. In addition, in the transmissive area, at least some of insulating layers, such as the barrier layer 112, the buffer layer 111, the first interlayer insulating film 160, and the second interlayer insulating film may be omitted to further improve the transmittance. The third light-emitting element ED3 may be positioned in the transmissive area. That is, the third light-emitting element ED3 may overlap an electronic module positioned in the transmissive area. Some of the plurality of third light-emitting elements ED3 positioned in the third display area may overlap the third pixel circuit part PC3, and some other thereof may be positioned in the transmissive area. As such, the display area of the display device according to one or more embodiments may be further increased by allowing a screen to be displayed even in a portion in which various electronic modules are positioned.

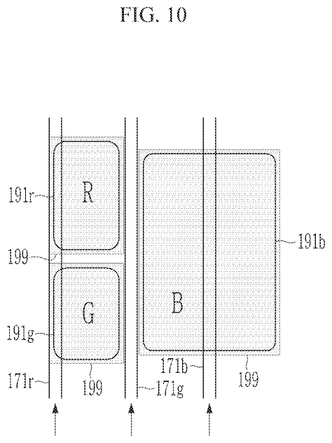

The examples of the structure of each pixel positioned in the first display area, the second display area, and the third display area of the display device according to one or more embodiments has been described above. The display device according to one or more embodiments may secure the additional capacitance by allowing the additional capacitor electrode positioned on the same layer as the extension electrode to overlap the pixel electrode. Hereinafter, various planar shapes of the additional capacitor electrode and the pixel electrode will be described with reference to FIG. 10 to FIG. 15. The planar shapes of the additional capacitor electrode and the pixel electrode shown in FIG. 10 to FIG. 15 are applicable to the first display area, the second display area, and the third display area, respectively.

FIG. 10 to FIG. 15 illustrate top plan views of some constituent elements of a display device according to one or more embodiments. FIG. 10 to FIG. 15 show a data line, an additional capacitor, and a pixel electrode. A plurality of pixels may include a red pixel R for displaying red, a green pixel G for displaying green, and a blue pixel B for displaying blue. FIG. 10 to FIG. 15 show one red pixel R and a first data line 171r connected thereto, one green pixel G and a second data line 171g connected thereto, and one blue pixel B and a third data line 171b connected thereto.

First, as shown in FIG. 10, a display device according to one or more embodiments includes a pixel electrode 191r of the red pixel R, a pixel electrode 191g of the green pixel G, a pixel electrode 191b of the blue pixel B, and an additional capacitor electrode 199 overlapping respective pixel electrodes 191r, 191g, and 191b.

The pixel electrode 191r of the red pixel R, the pixel electrode 191g of the green pixel G, and the pixel electrode 191b of the blue pixel B are located to be spaced apart from each other by an interval (e.g., a predetermined interval). The pixel electrode 191r of the red pixel R and the pixel electrode 191g of the green pixel G may be positioned to be adjacent to each other along a column direction. The pixel electrode 191b of the blue pixel B may be positioned to be adjacent to the pixel electrode 191r of the red pixel R along a row direction, and may be positioned to be adjacent to the pixel electrode 191g of the green pixel G along the row direction. The pixel electrode 191r of the red pixel R, the pixel electrode 191g of the green pixel G, and the pixel electrode 191b of the blue pixel B may have a substantially quadrangular shape in a plan view. Corner portions of the pixel electrode 191r of the red pixel R, the pixel electrode 191g of the green pixel G, and the pixel electrode 191b of the blue pixel B may have a rounded shape. A length in the column direction of the pixel electrode 191b of the blue pixel B may approximately correspond to a sum of a length in the column direction of the pixel electrode 191r of the red pixel R and a length in the column direction of the pixel electrode 191g of the green pixel G. However, the disposition shapes and planar shapes of the pixel electrode 191r of the red pixel R, the pixel electrode 191g of the green pixel G, and the pixel electrode 191b of the blue pixel B are only examples, and these may be variously changed.

The additional capacitor electrode(s) 199 overlaps the pixel electrode 191r of the red pixel R, the pixel electrode 191g of the green pixel G, and the pixel electrode 191b of the blue pixel B. The additional capacitor electrode 199 may substantially entirely overlap the pixel electrode 191r of the red pixel R, may substantially entirely overlap the pixel electrode 191g of the green pixel G, and may substantially entirely overlap the pixel electrode 191b of the blue pixel B. In one or more embodiments, an extension electrode connected to respective pixel electrodes 191r, 191g, and 191b may be positioned on the same layer as the additional capacitor electrode 199, and the extension electrode is separated from the additional capacitor electrode 199. A portion of the additional capacitor electrode 199 overlapping the pixel electrode 191r of the red pixel R, a portion of the additional capacitor electrode 199 overlapping the pixel electrode 191g of the green pixel G, and a portion of the additional capacitor electrode 199 overlapping the pixel electrode 191b of the blue pixel B may be spaced apart from each other. The planar shape of the additional capacitor electrode 199 may correspond to the planar shapes of the pixel electrode 191r of the red pixel R, the pixel electrode 191g of the green pixel G, and the pixel electrode 191b of the blue pixel B. The additional capacitor electrode 199, or the respective portions thereof, may be substantially quadrangle in a plan view.

The display device according to one or more embodiments may further include the first data line 171r, the second data line 171g, and the third data line 171b. The first data line 171r, the second data line 171g, and the third data line 171b may be sequentially located to be spaced apart from each other by an interval (e.g., predetermined interval). The first data line 171r, the second data line 171g, and the third data line 171b may extend long along the column direction, and may be located to be spaced apart from each other along the row direction. The pixel electrode 191r of a red pixel R and the pixel electrode 191g of a green pixel G may be positioned between the first data line 171r and the second data line 171g. The pixel electrode 191r of the red pixel R and the pixel electrode 191g of the green pixel G may overlap the first data line 171r or the second data line 171g. However, the present disclosure is not limited thereto, and the pixel electrode 191r of the red pixel R and the pixel electrode 191g of the green pixel G might not overlap the first data line 171r and the second data line 171g. The pixel electrode 191b of the blue pixel B may be positioned at both sides of the third data line 171b. The pixel electrode 191b of the blue pixel B may overlap the third data line 171b.

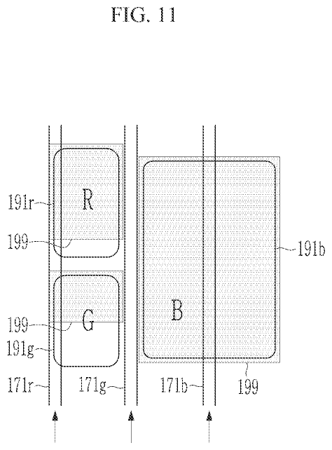

In the embodiments corresponding to FIG. 11, an overlapping area of the additional capacitor electrode(s) 199 and each of the pixel electrodes 191r, 191g, and 191b may be different from that of the embodiments corresponding to FIG. 10. The additional capacitor electrode 199 may partially overlap the pixel electrode 191r of the red pixel R, may partially overlap the pixel electrode 191g of the green pixel G, and may substantially entirely overlap the pixel electrode 191b of the blue pixel B. The overlapping area of the additional capacitor electrode 199 and each of the pixel electrodes 191r, 191g, and 191b may be variously design-changed. An overlapping ratio of the additional capacitor electrode 199 and the pixel electrode 191r of the red pixel R, an overlapping ratio of the additional capacitor electrode 199 and the pixel electrode 191g of the green pixel G, and an overlapping ratio of the additional capacitor electrode 199 and the pixel electrode 191b of the blue pixel B, may be different from each other. Capacitance of the additional capacitor of each pixel may be adjusted according to their overlapping area.

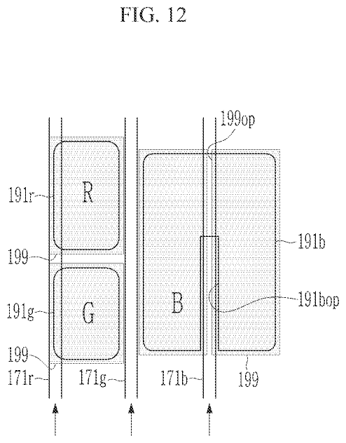

In the embodiments corresponding to FIG. 12, the planar shapes of the pixel electrode 191b of the blue pixel B, and the portion of the additional capacitor electrode 199 overlapping therewith, may be different from those of the embodiments corresponding to FIG. 10. The pixel electrode 191b of the blue pixel B may include an opening 191bop, and the opening 191bop may overlap the third data line 171b. By forming the opening 191bop in the pixel electrode 191b of the blue pixel B, the overlapping area of the pixel electrode 191b of the blue pixel B and the third data line 171b may be reduced, thereby reducing parasitic capacitance. The additional capacitor electrode 199 may include an opening 199op, and the opening 199op may overlap the third data line 171b. By the opening 199op, portions of the additional capacitor electrode 199 positioned at both sides of the third data line 171b may be separated from each other. By forming the opening 199op in the additional capacitor electrode 199, the overlapping area between the additional capacitor electrode 199 and the third data line 171b may be reduced, thereby reducing parasitic capacitance. The opening 191bop of the pixel electrode 191b of the blue pixel B and the opening 199op of the additional capacitor electrode 199 may overlap each other.

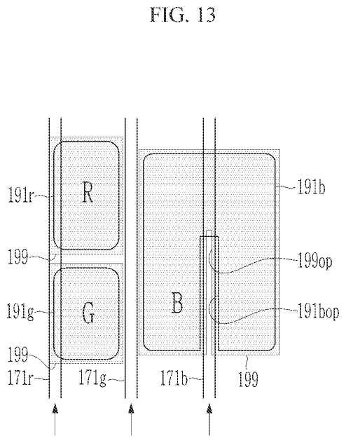

In the embodiments corresponding to FIG. 13, the planar shape of the additional capacitor electrode 199 may be different from that of the embodiments corresponding to FIG. 12. The additional capacitor electrode 199 may include an opening 199op, and the opening 199op may overlap the third data line 171b. A portion of the additional capacitor electrode 199 positioned at the left side of the third data line 171b, and a portion of the additional capacitor electrode 199 positioned at the right side of the third data line 171b, may be connected not to be separated from each other.

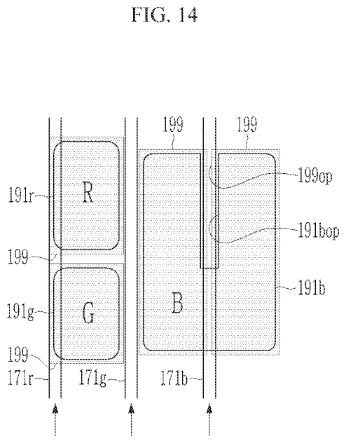

In the embodiments corresponding to FIG. 14, the planar shape of the pixel electrode 191b of the blue pixel B may be different from that of the embodiments corresponding to FIG. 12. In the embodiments corresponding to FIG. 12, the opening 191bop of the pixel electrode 191b of the blue pixel B may be positioned at a lower center thereof, and in the embodiments corresponding to FIG. 13, the opening 191bop of the pixel electrode 191b of the blue pixel B may be positioned at an upper center thereof. However, the formation position and size of the opening 191bop of the pixel electrode 191b of the blue pixel B may be variously changed.

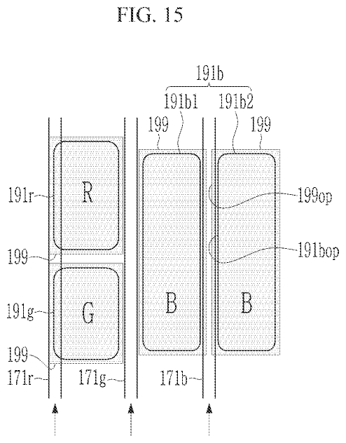

In the embodiments corresponding to FIG. 15, the planar shape of the pixel electrode 191b of the blue pixel B may be different from that of the embodiments corresponding to FIG. 12. The pixel electrode 191b of the blue pixel B may include an opening 191bop, and the opening 191bop may overlap the third data line 171b. By the opening 191bop, a first portion 191b1 of the pixel electrode 191b of the blue pixel B positioned at the left side of the third data line 171b, and a second portion 191b2 of the pixel electrode 191b of the blue pixel B positioned at the right side of the third data line 171b, may be separated from each other. The first portion 191b1 and the second portion 191b2 of the pixel electrode 191b of the blue pixel B may be electrically connected to each other to receive the same voltage.

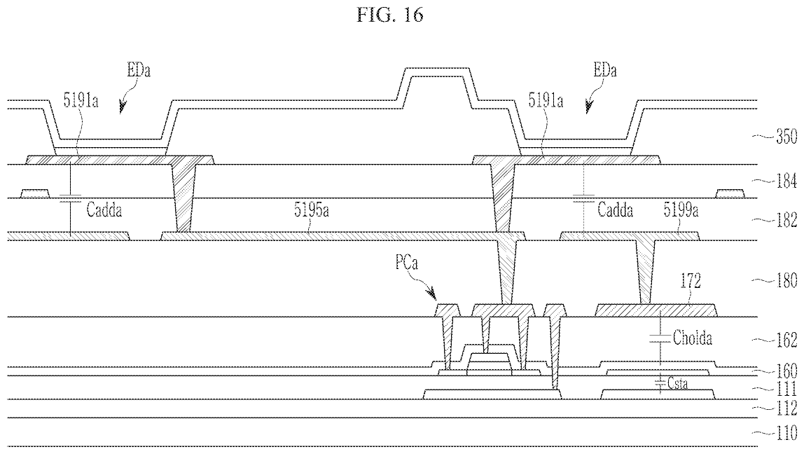

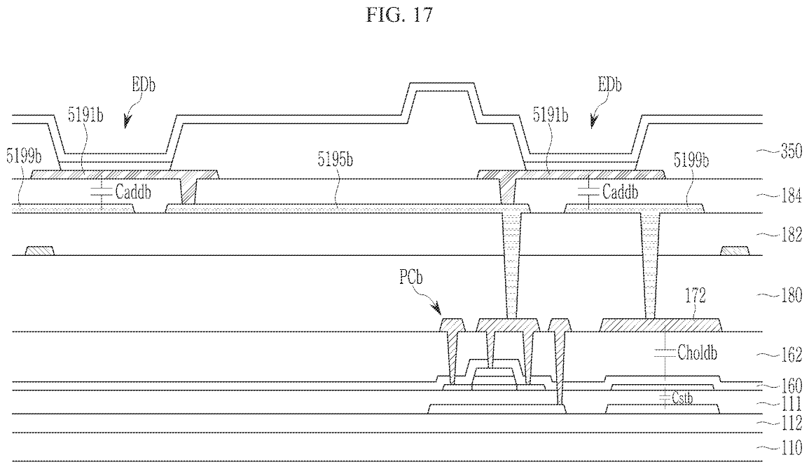

Hereinafter, a display device according to one or more embodiments will be described with reference to FIG. 16 and FIG. 17.

Because many portions of the display device according to one or more embodiments shown in FIG. 16 and FIG. 17 are the same as those of the display device according to one or more embodiments shown in FIG. 1 to FIG. 9, a repeated description thereof will be omitted. One or more embodiments may be different from the previously described embodiments in that a fifth conductive layer is further included, which will be further described below.

FIG. 16 and FIG. 17 illustrate cross-sectional views of a display device according to one or more embodiments. FIG. 16 and FIG. 17 show cross-sections of different pixels positioned in the third display area of the display device according to one or more embodiments. For convenience, the pixel illustrated in FIG. 16 is referred to as a first pixel, and the pixel illustrated in FIG. 17 is referred to as a second pixel.

As shown in FIG. 16, the first pixel of the display device according to one or more embodiments includes a substrate 110, a pixel circuit part PCa positioned on the substrate 110, and a light-emitting element EDa connected to the pixel circuit part PCa. The pixel circuit part PCa and the light-emitting element EDa are connected by an extension electrode 5195a. In addition, the display device according to one or more embodiments further includes a storage capacitor Csta, a hold capacitor Cholda, and an additional capacitor Cadda.

As shown in FIG. 17, the second pixel of the display device according to one or more embodiments includes a substrate 110, a pixel circuit part PCb positioned on the substrate 110, and a light-emitting element EDb connected to the pixel circuit part PCb. The pixel circuit part PCb and the light-emitting element EDb are connected by an extension electrode 5195b. In addition, the display device according to one or more embodiments further includes a storage capacitor Cstb, a hold capacitor Choldb, and an additional capacitor Caddb.

In one or more of the previously described embodiments, the extension electrodes and additional capacitor electrodes of all the pixels may be positioned in the fourth conductive layer. In one or more embodiments, the extension electrodes of some pixels and the extension electrodes of other pixels may be positioned on different layers, and the additional capacitor electrodes of some pixels and the additional capacitor electrodes of other pixels may be positioned on different layers. The display device according to the one or more embodiments further includes a fifth conductive layer and a third passivation film 184, and the fifth conductive layer may be positioned between the second passivation film 182 and the third passivation film 184. The third passivation film 184 may be positioned on the fifth conductive layer and the second passivation film 182, and the light-emitting elements EDa and EDb may be positioned on the third passivation film 184.

In the first pixel, the extension electrode 5195a and the additional capacitor electrode 5199a may be positioned in the fourth conductive layer. The light-emitting element EDa may include a pixel electrode 5191a, and the pixel electrode 5191a may be connected to the extension electrode 5195a through an opening formed in the second passivation film 182 and the third passivation film 184. The additional capacitor electrode 5199a may be connected to the driving voltage line 172 through an opening formed in the first passivation film 180. The additional capacitor electrode 5199a may overlap the pixel electrode 5191a to form the additional capacitor Cadda. The second passivation film 182 and the third passivation film 184 may be positioned between the additional capacitor electrode 5199a and the pixel electrode 5191a.

In the second pixel, the extension electrode 5195b and an additional capacitor electrode 5199b may be positioned in the fifth conductive layer. The light-emitting element EDb may include a pixel electrode 5191b, and the pixel electrode 5191b may be connected to the extension electrode 5195b through an opening formed in the third passivation film 184. The additional capacitor electrode 5199b may be connected to the driving voltage line 172 through an opening formed in the first passivation film 180 and in the second passivation film 182. The additional capacitor electrode 5199b may overlap the pixel electrode 5191b to form the additional capacitor Caddb. The third passivation film 184 may be positioned between the additional capacitor electrode 5199b and the pixel electrode 5191b.

As described above, by differentiating layers in which the extension electrode and the additional capacitor electrode are positioned for each pixel, the distance between adjacent pixels may be designed to be closer, and resolution may be improved.

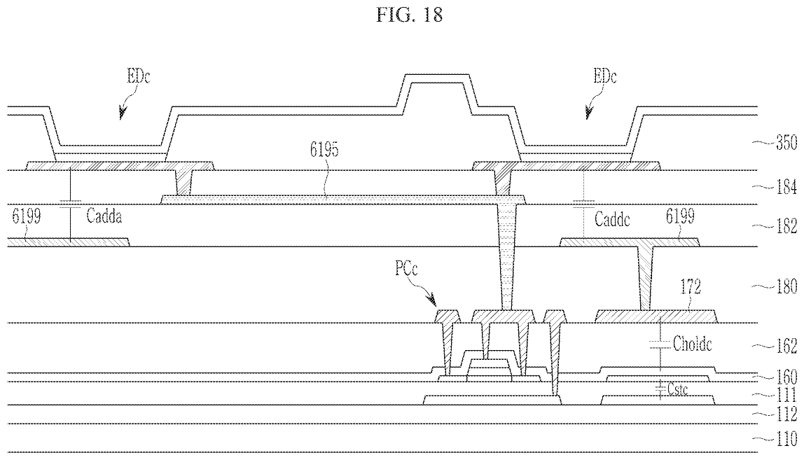

Hereinafter, a display device according to one or more embodiments will be described with reference to FIG. 18.

Because many portions of the display device according to one or more embodiments shown in FIG. 18 are the same as those of the display device according to one or more embodiments shown in FIG. 16 and FIG. 17, a repeated description thereof will be omitted. One or more embodiments may be different from the previously described embodiments in that the extension electrode and the additional capacitor electrode are positioned on different layers within the same pixel, which will be further described below.

FIG. 18 illustrates a cross-sectional view of a display device according to one or more embodiments.

As shown in FIG. 18, the display device according to one or more embodiments includes a substrate 110, a pixel circuit part PCc positioned on the substrate 110, and a light-emitting element EDc connected to the pixel circuit part PCc. The pixel circuit part PCc and the light-emitting element EDc are connected by an extension electrode 6195. In addition, the display device according to one or more embodiments further includes a storage capacitor Cstc, a hold capacitor Choldc, and an additional capacitor Caddc.

The extension electrodes of some pixels and the extension electrodes of other pixels may be positioned on different layers, and the additional capacitor electrodes of some pixels and the additional capacitor electrodes of other pixels may be positioned on different layers.

In one or more of the previously described embodiments, the extension electrode and the additional capacitor electrode may be positioned on the same layer in the same pixel, and in the presently described one or more embodiments, the extension electrode 6195 and an additional capacitor electrode 6199 may be positioned on different layers in the same pixel. For example, the extension electrode 6195 may be positioned in the fifth conductive layer, and the additional capacitor electrode 6199 may be positioned in the fourth conductive layer. In one or more embodiments, in another pixel, the extension electrode may be positioned on the fourth conductive layer, and the additional capacitor electrode may be positioned on the fifth conductive layer.

In the embodiments, it has been described that the extension electrode and the additional capacitor electrode are positioned on the fourth conductive layer or the fifth conductive layer, but the present disclosure is not limited thereto, and the display device according to one or more embodiments may include more conductive layers. For example, in some pixels, the extension electrode and the additional capacitor electrode are positioned on the fourth conductive layer, and in some other pixels, the extension electrode and the additional capacitor electrode are positioned on the fifth conductive layer, and in the remaining pixels, the extension electrode and the additional capacitor electrode are positioned on the sixth conductive layer.

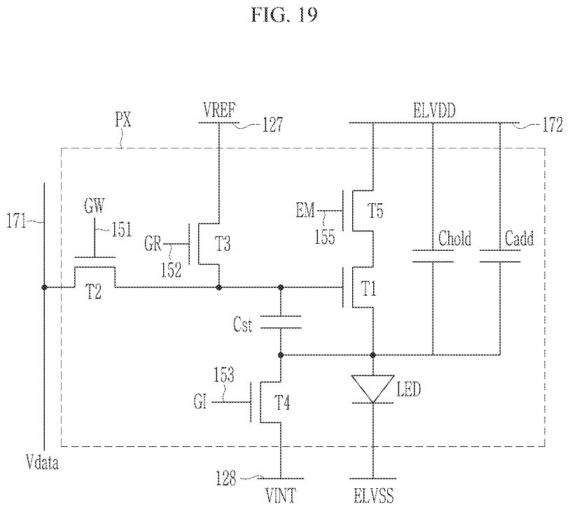

As described above, the structure of the pixel circuit part of each pixel of the display device according to one or more embodiments may be variously changed, and one or more other embodiments will be described below with reference to FIG. 19.

FIG. 19 illustrates a circuit diagram of one pixel of a display device according to one or more embodiments.

As shown in FIG. 19, a display device according to one or more embodiments includes a plurality of pixels PX and a plurality of signal lines 127, 128, 151, 152, 153, 155, 171, and 172. One pixel PX includes a plurality of transistors T1, T2, T3, T4, and T5 respectively connected to the plurality of signal lines 127, 128, 151, 152, 153, 155, 171, and 172, a storage capacitor Cst, a hold capacitor Chold, an additional capacitor Cadd, and a light-emitting diode LED.

In one or more of the previously described embodiments, each of the transistors T1, T2, T3, T4, and T5 may have a dual-gate structure, and in the presently described one or more embodiments, each of the transistors T1, T2, T3, T4, and T5 may not have a dual-gate structure or may have a single-gate structure. That is, each of the transistors T1, T2, T3, T4, and T5 may include a single gate electrode. In addition, they may be changed to various circuits.

While this disclosure has been described in connection with what is presently considered to be practical embodiments, it is to be understood that the present disclosure is not limited to the disclosed embodiments, but, on the contrary, is intended to cover various modifications and equivalent arrangements included within the spirit and scope of the appended claims.

Description of Some Reference Characters

| | |
|---|---|
| DA1: first display area | DA2: second display area |
| DA3: third display area | PC1: first pixel circuit part |
| PC2: second pixel circuit part | PC3: third pixel circuit part |
| DR: driving circuit part | ED: light-emitting element |
| ED1: first light-emitting element | ED2: second light-emitting element |
| ED3: third light-emitting element | Cst, Cst1, Cst2, Cst3: storage capacitor |
| Chold, Chold1, Chold2, Chold3: hold capacitor | |
| Cadd, Cadd1, Cadd2, Cadd3: additional capacitor | |
| 172: driving voltage line | |
| 199, 1199, 2199, 3199: additional capacitor electrode | |
| 1191: first pixel electrode | 2191: second pixel electrode |
| 3191: third pixel electrode | 1195: first extension electrode |
| 2195: second extension electrode | 3195: third extension electrode |

What is claimed is:

1. A display device comprising:
a substrate;
a transistor above the substrate;
a pixel electrode connected to the transistor;
an extension electrode connected between the transistor and the pixel electrode;
an additional capacitor electrode at a same layer as the extension electrode, overlapping the pixel electrode, and to which a constant voltage is applied;
a light-emitting layer above the pixel electrode; and
a common electrode above the light-emitting layer.

2. The display device of claim 1, wherein the extension electrode and the additional capacitor electrode comprise a transparent conductive oxide.

3. The display device of claim 1, wherein the additional capacitor electrode is connected to a driving voltage line to which a driving voltage is applied.

4. The display device of claim 3, wherein the transistor comprises:
a first gate electrode above the substrate;
a semiconductor that overlaps the first gate electrode, and that comprises a first area, a channel, and a second area;
a second gate electrode overlapping the channel;
a source electrode connected to the first area; and
a drain electrode connected to the second area, and connected to the pixel electrode.

5. The display device of claim 4, wherein the drain electrode is connected to the second gate electrode.

6. The display device of claim 4, wherein the driving voltage line is at a same layer as the source electrode and the drain electrode.

7. The display device of claim 4, further comprising:
a first storage electrode at a same layer as the semiconductor; and
a second storage electrode at a same layer as the first gate electrode, and overlapping the first storage electrode.

8. The display device of claim 7, wherein the first storage electrode overlaps the driving voltage line.

9. The display device of claim 4, wherein the semiconductor comprises an oxide semiconductor material.

10. The display device of claim 1, wherein the substrate comprises a display area, and a peripheral area adjacent to the display area, and
wherein the display area comprises a first display area, a second display area outside the first display area, and a third display area inside the first display area.

11. The display device of claim 10, wherein, in the first display area, the transistor is connected to the pixel electrode through the extension electrode, and
wherein, in the second display area and in the third display area, respective transistors are connected to respective pixel electrodes through respective extension electrodes.

12. The display device of claim 11, further comprising a driving circuit part in the second display area,
wherein at least some of the pixel electrodes in the second display area overlap the driving circuit part.

13. The display device of claim 12, further comprising an electronic module in the third display area,
wherein at least some of the pixel electrodes in the third display area overlap the electronic module.

14. The display device of claim 1, wherein the pixel electrode comprises:
a pixel electrode of a red pixel;
a pixel electrode of a green pixel; and
a pixel electrode of a blue pixel.

15. The display device of claim 14, wherein the additional capacitor electrode overlaps all of the pixel electrode of the red pixel, all of the pixel electrode of the green pixel, and all of the pixel electrode of the blue pixel.

16. The display device of claim 14, wherein the additional capacitor electrode does not overlap at least some of the pixel electrode of the red pixel, the pixel electrode of the green pixel, or the pixel electrode of the blue pixel.

17. The display device of claim 16, wherein an overlapping ratio of the additional capacitor electrode and the pixel electrode of the red pixel, an overlapping ratio of the additional capacitor electrode and the pixel electrode of the green pixel, and an overlapping ratio of the additional capacitor electrode and the pixel electrode of the blue pixel are different.

18. The display device of claim 14, further comprising a data line to which a data voltage is applied,
wherein the pixel electrode of the blue pixel defines an opening that overlaps the data line, and
wherein the additional capacitor electrode defines an opening that overlaps the data line.

19. The display device of claim 1, wherein each of pixels comprises the extension electrode, and
wherein an extension electrode of a first pixel and an extension electrode of a second pixel are at different respective layers.

20. The display device of claim 19, wherein each of the pixels comprises the additional capacitor electrode, and
wherein an additional capacitor electrode of the first pixel and an additional capacitor electrode of the second pixel are at different respective layers.
